(19) United States
(12) Patent Application Publication
(10) Pub. No.: US 2026/0223688 A1
(43) Pub. Date: Jul. 30, 2026

(54) INTERPOSER

(71) Applicant: Panasonic Intellectual Property Management Co., Ltd., Osaka (JP)

(72) Inventors: Naoki TORAZAWA, Osaka (JP); Tatsuya KABE, Osaka (JP)

(73) Assignee: Panasonic Intellectual Property Management Co., Ltd., Osaka (JP)

(21) Appl. No.: 19/150,749

(22) PCT Filed: Jan. 29, 2024
(86) PCT No.: PCT/JP2024/002675

§ 371 Date: Jul. 24, 2025

(30) Foreign Application Priority Data
Feb. 6, 2023 (JP) 2023-016287

(51) Int. Cl. H10W 44/00; H10W 70/63; H10W 70/685; H10W 70/695

(52) U.S. Cl. CPC H10W 44/601; H10W 70/63; H10W 70/685; H10W 70/695

(57) ABSTRACT

In an interposer, a first capacitor and a second capacitor are built in a dielectric substrate The first capacitor and the second capacitor have mutually different capacitances. The first capacitor includes a first electrode and a second electrode and a first dielectric portion. The second capacitor includes a third electrode and a fourth electrode and a second dielectric portion. The thickness of the second dielectric portion of the second capacitor is less than the thickness of the first dielectric portion of the first capacitor. The capacitance of the second capacitor is greater than the capacitance of the first capacitor.

### TECHNICAL FIELD

The present disclosure generally relates to an interposer, and more particularly relates to an interposer including a built-in capacitor.

### BACKGROUND ART

A package board including an embedded thin film capacitor has been known in the art as an interposer (see, for example, Patent Literature 1). Patent Literature 1 discloses a package assembly including: a package board; a die bonded to the package board by flip-chip bonding; and a printed circuit board bonded to the package board via solder balls.

Generally speaking, an interposer is required to not only include a plurality of capacitors with mutually different capacitances but also have a reduced size.

### CITATION LIST

### Patent Literature

Patent Literature 1: JP 2017-130653 A

### SUMMARY OF INVENTION

An object of the present disclosure is to provide an interposer which includes a plurality of capacitors with mutually different capacitances and yet may contribute to downsizing.

An interposer according to an aspect of the present disclosure includes a dielectric substrate, a wiring portion, and a first capacitor and a second capacitor. The dielectric substrate has a first principal surface and a second principal surface opposite from the first principal surface. The wiring portion penetrates through the dielectric substrate. The first capacitor and the second capacitor are built in the dielectric substrate. The first capacitor and the second capacitor have mutually different capacitances. The first capacitor includes a first electrode and a second electrode, and a first dielectric portion. The first electrode and the second electrode face each other in a thickness direction defined with respect to the dielectric substrate. The first dielectric portion is interposed between the first electrode and the second electrode. The second capacitor includes a third electrode and a fourth electrode, and a second dielectric portion. The third electrode and the fourth electrode face each other in the thickness direction defined with respect to the dielectric substrate. The second dielectric portion is interposed between the third electrode and the fourth electrode. The thickness of the second dielectric portion is less than the thickness of the first dielectric portion. The capacitance of the second capacitor is greater than the capacitance of the first capacitor.

### BRIEF DESCRIPTION OF DRAWINGS

FIG. 1 is a cross-sectional view of an interposer according to a first embodiment;

FIGS. 2A-2D are cross-sectional views illustrating respective process steps of a method for fabricating the interposer;

FIGS. 3A-3C are cross-sectional views illustrating respective process steps of the method for fabricating the interposer;

FIG. 4 is a cross-sectional view of an interposer according to a second embodiment;

FIGS. 5A-5D are cross-sectional views illustrating respective process steps of a method for fabricating the interposer;

FIGS. 6A-6C are cross-sectional views illustrating respective process steps of the method for fabricating the interposer;

FIGS. 7A and 7B are cross-sectional views illustrating respective process steps of the method for fabricating the interposer;

FIG. 8A is a plan view of a main part illustrating a method for fabricating an interposer according to a variation of the second embodiment; and FIG. 8B is a cross-sectional view thereof taken along the plane X1-X1 shown in FIG. 8A; and

FIG. 9 is a cross-sectional view of a main part illustrating a comparative example of a method for fabricating an interposer.

### DESCRIPTION OF EMBODIMENTS

The drawings to be referred to in the following description of embodiments are all schematic representations. Thus, the ratio of the dimensions (including thicknesses) of respective constituent elements illustrated on the drawings does not always reflect their actual dimensional ratio.

### First Embodiment

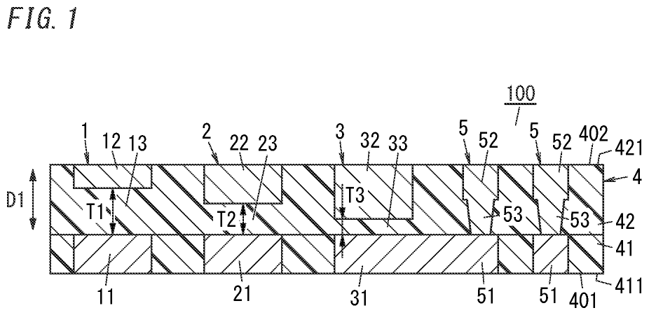

An interposer 100 according to a first embodiment will now be described with reference to FIG. 1.

### (1) Overview

An interposer 100 according to the first embodiment is interposed, for example, between a plurality of semiconductor chips and a system in package (SiP) package board. Examples of the plurality of semiconductor chips include a processor, a logic integrated circuit (IC), and a memory (such as a high bandwidth memory (HBM)).

The interposer 100 according to the first embodiment includes a dielectric substrate 4, a plurality of wiring portions 5, a first capacitor 1, a second capacitor 2, and a third capacitor 3. The plurality of wiring portions 5 penetrate through the dielectric substrate 4. Note that only two out of the plurality of wiring portions 5 are shown in FIG. 1.

The first capacitor 1, the second capacitor 2, and the third capacitor 3 are built in the dielectric substrate 4. The first capacitor 1, the second capacitor 2, and the third capacitor 3 have mutually different capacitances.

### (2) Details

The dielectric substrate 4 has a first principal surface 401 and a second principal surface 402 opposite from the first principal surface 401. When viewed in plan in a thickness direction D1 defined with respect to the dielectric substrate 4, the outer edges of the dielectric substrate 4 have a rectangular shape. However, this is only an example and should not be construed as limiting.

The dielectric substrate 4 includes a first dielectric layer 41 and a second dielectric layer 42. The second dielectric layer 42 is stacked on the first dielectric layer 41. The first principal surface 401 of the dielectric substrate 4 is defined by a principal surface 411, facing away from the second dielectric layer 42, of the first dielectric layer 41. The second principal surface 402 of the dielectric substrate 4 is defined by a principal surface 421, facing away from the first dielectric layer 41, of the second dielectric layer 42.

A material for the first dielectric layer 41 includes an organic material (such as a polyimide resin, a bismaleimide resin, or a fluororesin).

A material for the second dielectric layer 42 includes an organic material (such as a polyimide resin, a bismaleimide resin, or a fluororesin). In this embodiment, the material for the second dielectric layer 42 is the same as the material for the first dielectric layer 41. Alternatively, the material for the second dielectric layer 42 may be different from the material for the first dielectric layer 41.

The first capacitor 1 includes a first electrode 11 and a second electrode 12, and a first dielectric portion 13. The first electrode 11 and the second electrode 12 face each other in the thickness direction D1 defined with respect to the dielectric substrate 4. The first dielectric portion 13 is interposed between the first electrode 11 and the second electrode 12. When viewed in plan in a thickness direction D1 defined with respect to the dielectric substrate 4, the outer edges of each of the first electrode 11 and the second electrode 12 have a rectangular shape. However, this is only an example and should not be construed as limiting.

In the first capacitor 1, the first electrode 11 is built in the first dielectric layer 41. The first electrode 11 is exposed out of the first principal surface 401 of the dielectric substrate 4. The first electrode 11 penetrates through the first dielectric layer 41. In the interposer 100, the thickness of the first electrode 11 is substantially equal to the thickness of the first dielectric layer 41 and the lower surface of the first electrode 11 is substantially flush with the first principal surface 401 of the dielectric substrate 4.

In addition, in the first capacitor 1, the second electrode 12 is built in the second dielectric layer 42. The second electrode 12 is exposed out of the second principal surface 402 of the dielectric substrate 4. The second electrode 12 does not penetrate through the second dielectric layer 42. The second electrode 12 is less thick than the second dielectric layer 42 and is exposed out of the second principal surface 402 of the dielectric substrate 4. In this interposer 100, the second electrode 12 is less thick than the second dielectric layer 42 and the upper surface of the second electrode 12 is substantially flush with the second principal surface 402 of the dielectric substrate 4.

Examples of materials for the first electrode 11 and the second electrode 12 include copper. However, the material for the first electrode 11 and the second electrode 12 does not have to be copper but may also be, for example, a copper alloy, aluminum, or titanium. In this embodiment the material for the second electrode 12 is the same as the material for the first electrode 11. However, this is only an example and should not be construed as limiting. Alternatively, the material for the second electrode 12 may be different from the material for the first electrode 11.

In this interposer 100, the material for the first dielectric portion 13 is the same as the material for the second dielectric layer 42 and includes an organic material. The thickness T1 of the first dielectric portion 13 is less than the thickness of the second dielectric layer 42. The first dielectric portion 13 overlaps with the second dielectric layer 42 in a direction perpendicular to the thickness direction D1 defined with respect to the dielectric substrate 4. The first dielectric portion 13 is formed integrally with the second dielectric layer 42.

The second capacitor 2 includes a third electrode 21 and a fourth electrode 22, and a second dielectric portion 23. The third electrode 21 and the fourth electrode 22 face each other in the thickness direction D1 defined with respect to the dielectric substrate 4. The second dielectric portion 23 is interposed between the third electrode 21 and the fourth electrode 22. When viewed in plan in a thickness direction D1 defined with respect to the dielectric substrate 4, the outer edges of each of the third electrode 21 and the fourth electrode 22 have a rectangular shape. However, this is only an example and should not be construed as limiting.

In the second capacitor 2, the third electrode 21 is built in the first dielectric layer 41. The third electrode 21 is exposed out of the first principal surface 401 of the dielectric substrate 4. The third electrode 21 penetrates through the first dielectric layer 41. In the interposer 100, the third electrode 21 is substantially as thick as the first dielectric layer 41 and the lower surface of the third electrode 21 is substantially flush with the first principal surface 401 of the dielectric substrate 4.

In addition, in the second capacitor 2, the fourth electrode 22 is built in the second dielectric layer 42. The fourth electrode 22 is exposed out of the second principal surface 402 of the dielectric substrate 4. The fourth electrode 22 does not penetrate through the second dielectric layer 42. The fourth electrode 22 is less thick than the second dielectric layer 42 and is exposed out of the second principal surface 402 of the dielectric substrate 4. In this interposer 100, the fourth electrode 22 is less thick than the second dielectric layer 42 and the upper surface of the fourth electrode 22 is substantially flush with the second principal surface 402 of the dielectric substrate 4.

Examples of materials for the third electrode 21 and fourth electrode 22 include copper. However, the material for the third electrode 21 and the fourth electrode 22 does not have to be copper but may also be, for example, a copper alloy, aluminum, or titanium. In this embodiment the material for the fourth electrode 22 is the same as the material for the third electrode 21. However, this is only an example and should not be construed as limiting. Alternatively, the material for the fourth electrode 22 may be different from the material for the third electrode 21. Nevertheless, the material for the third electrode 21 is the same as the material for the first electrode 11. Also, the material for the fourth electrode 22 is the same as the material for the second electrode 12.

In this interposer 100, the material for the second dielectric portion 23 is the same as the material for the second dielectric layer 42 and includes an organic material. The thickness T2 of the second dielectric portion 23 is less than the thickness of the second dielectric layer 42. The second dielectric portion 23 overlaps with the second dielectric layer 42 in a direction perpendicular to the thickness direction D1 defined with respect to the dielectric substrate 4. The second dielectric portion 23 is formed integrally with the second dielectric layer 42.

The third capacitor 3 includes a fifth electrode 31 and a sixth electrode 32, and a third dielectric portion 33. The fifth electrode 31 and the sixth electrode 32 face each other in the thickness direction D1 defined with respect to the dielectric substrate 4. The third dielectric portion 33 is interposed between the fifth electrode 31 and the sixth electrode 32. When viewed in plan in a thickness direction D1 defined with respect to the dielectric substrate 4, the outer edges of each of the fifth electrode 31 and the sixth electrode 32 have a rectangular shape. However, this is only an example and should not be construed as limiting.

In the third capacitor 3, the fifth electrode 31 is built in the first dielectric layer 41. The fifth electrode 31 is exposed out of the first principal surface 401 of the dielectric substrate 4. The fifth electrode 31 penetrates through the first dielectric layer 41. In the interposer 100, the fifth electrode 31 is substantially as thick as the first dielectric layer 41 and the lower surface of the fifth electrode 31 is substantially flush with the first principal surface 401 of the dielectric substrate 4.

In addition, in the third capacitor 3, the sixth electrode 32 is built in the second dielectric layer 42. The sixth electrode 32 is exposed out of the second principal surface 402 of the dielectric substrate 4. The sixth electrode 32 does not penetrate through the second dielectric layer 42. The sixth electrode 32 is less thick than the second dielectric layer 42 and is exposed out of the second principal surface 402 of the dielectric substrate 4. In this interposer 100, the sixth electrode 32 is less thick than the second dielectric layer 42 and the upper surface of the sixth electrode 32 is substantially flush with the second principal surface 402 of the dielectric substrate 4.

Examples of materials for the fifth electrode 31 and the sixth electrode 32 include copper. However, the material for the fifth electrode 31 and the sixth electrode 32 does not have to be copper but may also be, for example, a copper alloy, aluminum, or titanium. In this embodiment the material for the sixth electrode 32 is the same as the material for the fifth electrode 31. However, this is only an example and should not be construed as limiting. Alternatively, the material for the sixth electrode 32 may be different from the material for the fifth electrode 31. Nevertheless, the material for the fifth electrode 31 is the same as the material for the first electrode 11. Also, the material for the sixth electrode 32 is the same as the material for the second electrode 12.

In this interposer 100, the material for the third dielectric portion 33 is the same as the material for the second dielectric layer 42 and includes an organic material. The thickness T3 of the third dielectric portion 33 is less than the thickness of the second dielectric layer 42. The third dielectric portion 33 overlaps with the second dielectric layer 42 in a direction perpendicular to the thickness direction D1 defined with respect to the dielectric substrate 4. The third dielectric portion 33 is formed integrally with the second dielectric layer 42.

Each of the plurality of wiring portions 5 includes a first conductor portion 51, a second conductor portion 52, and a via conductor portion 53. The respective first conductor portions 51 are built in the first dielectric layer 41. Each of the first conductor portions 51 penetrates through the first dielectric layer 41. In the interposer 100, each of the first conductor portions 51 is substantially as thick as the first dielectric layer 41 and the lower surface of the first conductor portion 51 is substantially flush with the first principal surface 401 of the dielectric substrate 4. The respective second conductor portions 52 are built in the second dielectric layer 42. Each of the second conductor portions 52 is less thick than the second dielectric layer 42 and is exposed out of the second principal surface 402 of the dielectric substrate 4. In the interposer 100, each of the second conductor portions 52 is less thick than the second dielectric layer 42 and the upper surface of the second conductor portion 52 is substantially flush with the second principal surface 402 of the dielectric substrate 4. The via conductor portions 53 are built in in the second dielectric layer 42. Each of the via conductor portions 53 connects a corresponding one of the first conductor portions 51 to a corresponding one of the second conductor portions 52. When viewed in plan in the thickness direction D1 defined with respect to the dielectric substrate 4, the via conductor portion 53 is smaller the corresponding first conductor portion 51 or the corresponding second conductor portion 52. Also, when viewed in plan in the thickness direction D1 defined with respect to the dielectric substrate 4, the outer edge of the via conductor portion 53 has a circular shape. However, this is only an example and should not be construed as limiting. In each of the plurality of wiring portions 5, the via conductor portion 53 is formed integrally with the second conductor portion 52. That is to say, in each of the plurality of wiring portions 5, the via conductor portion 53 is connected seamlessly to the second conductor portion 52.

In addition, in this interposer 100, the first conductor portion 51 in one of the two wiring portions 5 shown in FIG. 1 is connected to the fifth electrode 31 of the third capacitor 3. Optionally, the interposer 100 may further include another wiring portion connected to the first capacitor 1. The interposer 100 may further include still another wiring portion connected to the second capacitor 2.

In this interposer 100, the thickness T2 of the second dielectric portion 23 is less than the thickness T1 of the first dielectric portion 13 and the capacitance of the second capacitor 2 is greater than the capacitance of the first capacitor 1. In addition, in this interposer 100, the thickness T3 of the third dielectric portion 33 is less than the thickness T2 of the second dielectric portion 23 and the capacitance of the third capacitor 3 is greater than the capacitance of the second capacitor 2. Supposing the capacitance of the first capacitor 1 is C1, the dielectric constant of the first dielectric portion 13 is ε1, and a facing area in which the first electrode 11 and the second electrode 12 face each other is S1, the capacitance of the first capacitor 1 is calculated by C1=ε1·S1/T1. Supposing the capacitance of the second capacitor 2 is C2, the dielectric constant of the second dielectric portion 23 is ε2, and a facing area in which the third electrode 21 and the fourth electrode 22 face each other is S2, the capacitance of the second capacitor 2 is calculated by C2=ε2·S2/T2. Supposing the capacitance of the third capacitor 3 is C3, the dielectric constant of the third dielectric portion 33 is ε3, and a facing area in which the fifth electrode 31 and the sixth electrode 32 face each other is S3, the capacitance of the third capacitor 3 is calculated by C3=ε3·S3/T3. In this interposer 100, ε1=ε2=ε3 and T1>T2>T3 are satisfied, and therefore, [capacitive density of first capacitor 1]<[capacitive density of second capacitor 2]<[capacitive density of third capacitor 3] is satisfied. Thus, if S1=S2=S3 is satisfied, then C1<C2<C3 is satisfied.

In this interposer 100, when viewed in plan in the thickness direction D1 defined with respect to the dielectric substrate 4, the area of the first capacitor 1 (which is equal to the facing area S1), the area of the second capacitor 2 (which is equal to the facing area S2), and the area of the third capacitor 3 (which is equal to the facing area S3) are equal to each other. However, this is only an example and should not be construed as limiting. Alternatively, these areas of the capacitors 1, 2, 3 may be different from each other. The area of the first capacitor 1 when viewed in plan in the thickness direction D1 defined with respect to the dielectric substrate 4 is defined by the area of a part, overlapping with the first electrode 11, of the second electrode 12 when viewed in plan in the thickness direction D1 defined with respect to the dielectric substrate 4. In the same way, the area of the second capacitor 2 when viewed in plan in the thickness direction D1 defined with respect to the dielectric substrate 4 is defined by the area of a part, overlapping with the third electrode 21, of the fourth electrode 22 when viewed in plan in the thickness direction D1 defined with respect to the dielectric substrate 4. In the same way, the area of the third capacitor 3 when viewed in plan in the thickness direction D1 defined with respect to the dielectric substrate 4 is defined by the area of a part, overlapping with the fifth electrode 31, of the sixth electrode 32 when viewed in plan in the thickness direction D1 defined with respect to the dielectric substrate 4.

### (3) Method for Fabricating Interposer

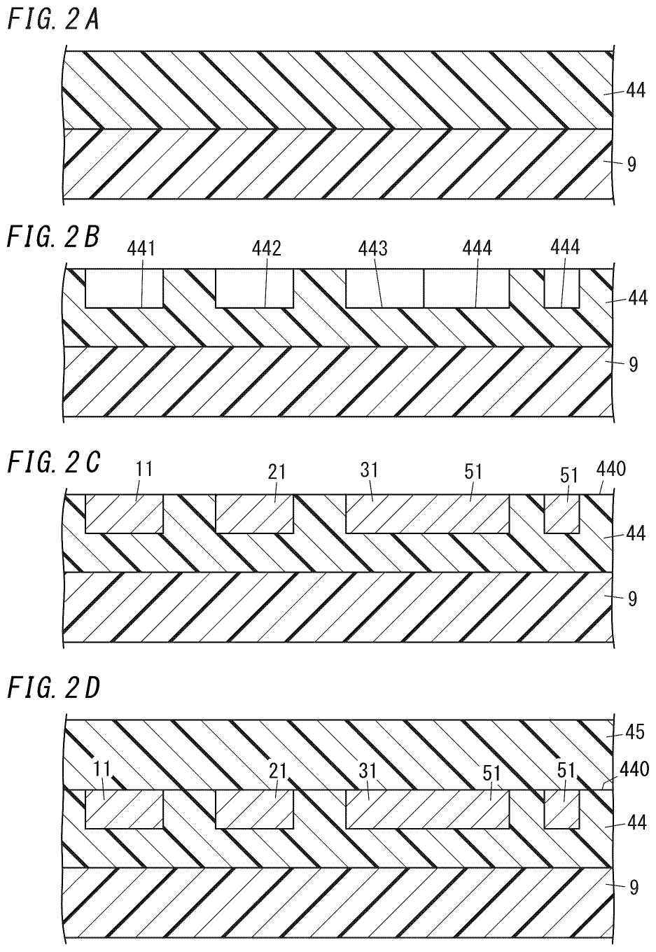

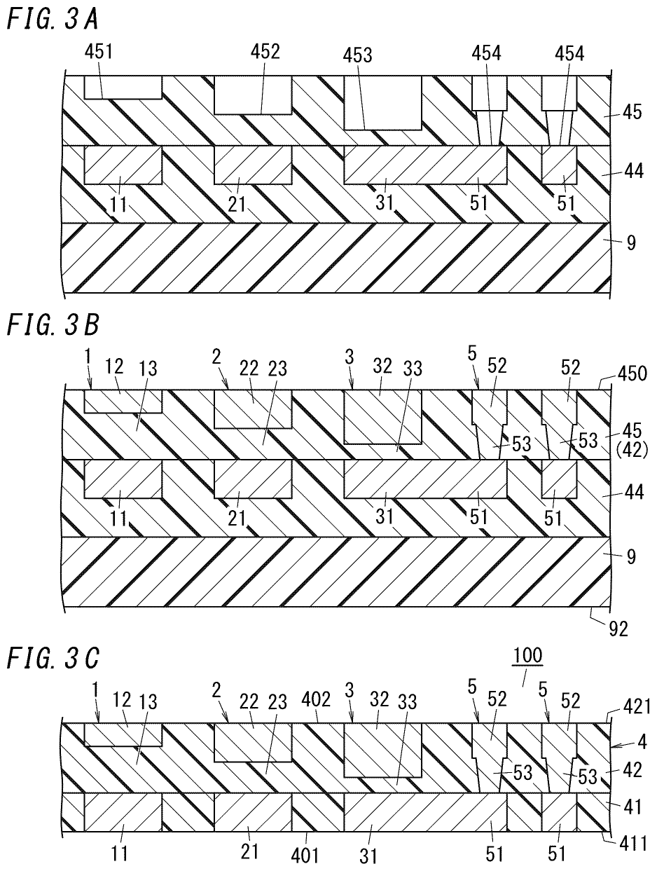

A method for fabricating an interposer 100 according to the first embodiment will be described with reference to FIGS. 2A-3C.

According to a method for fabricating the interposer 100, a supporting substrate 9 (refer to FIG. 2A) is provided and then first through seventh process steps are performed sequentially. The supporting substrate 9 may be, for example, an organic film, a silicon substrate, a glass substrate, or a metal substrate. Examples of the organic film include a liquid crystal polymer (LCP) film, a polyethylene terephthalate (PET) film, and a polytetrafluoroethylene (PTFE) film.

The first process step includes forming a first resin layer 44 as a prototype of the first dielectric layer 41 on the supporting substrate 9 as shown in FIG. 2A. Examples of materials for the first resin layer 44 include an organic material (resin material) for the first dielectric layer 41. The first resin layer 44 is thicker than the first dielectric layer 41. The first process step includes forming the first resin layer 44 by applying a solution including the organic material for the first dielectric layer 41 onto the supporting substrate 9 using a coater (such as a spin coater) or a dispenser and prebaking the organic material thus applied. Alternatively, the first process step may include forming the first resin layer 44 on the supporting substrate 9 by laminating a resin film to be the first resin layer 44 on the supporting substrate 9.

The second process step includes forming, in the first resin layer 44, a first recess 441, a second recess 442, a third recess 443, and a plurality of fourth recesses 444 which will respectively define regions where the first electrode 11, the third electrode 21, the fifth electrode 31, and the plurality of first conductor portions 51 will be formed as shown in FIG. 2B. In this embodiment, the second process step includes forming the first recess 441, the second recess 442, the third recess 443, and the plurality of fourth recesses 444 in the first resin layer 44 by imprinting process (such as thermal imprinting process). More specifically, the second process step includes, first, providing a first mold (first die) where a first uneven pattern, which is designed according to the respective shapes of the first electrode 11, the third electrode 21, the fifth electrode 31, and the plurality of first conductor portions 51, has been formed. The second process step further includes deforming the first resin layer 44 by pressing the first mold after that against the first resin layer 44 and then causing the first resin layer 44 to cure (e.g., thermally), thereby forming the first recess 441, the second recess 442, the third recess 443, and the plurality of fourth recesses 444 where the first electrode 11, the third electrode 21, the fifth electrode 31, and the plurality of first conductor portions 51 will be respectively formed. Then, the first mold is removed from the first resin layer 44. The opening shape of the first recess 441 corresponds to the outer edge shape of the first electrode 11 in plan view and the depth of the first recess 441 corresponds to the thickness of the first electrode 11. The opening shape of the second recess 442 corresponds to the outer edge shape of the third electrode 21 in plan view and the depth of the second recess 442 corresponds to the thickness of the third electrode 21. The opening shape of the third recess 443 corresponds to the outer edge shape of the fifth electrode 31 in plan view and the depth of the third recess 443 corresponds to the thickness of the fifth electrode 31. The opening shape of each of the plurality of fourth recesses 444 corresponds to the outer edge shape of the first conductor portion 51 in plan view and the depth of each of the fourth recesses 444 corresponds to the thickness of the first conductor portion 51. The first recess 441, the second recess 442, the third recess 443, and the plurality of fourth recesses 444 have the same depth. Note that the imprinting process does not have to be a thermal imprinting process but may also be an optical imprinting process, for example.

The third process step includes forming the first electrode 11, the third electrode 21, the fifth electrode 31, and the plurality of first conductor portions 51 as shown in FIG. 2C. More specifically, the third process step includes a first step, a second step, and a third step. The first step includes forming, by sputtering process, for example, a seed layer to cover the surface of the first resin layer 44. A material for the seed layer is the same as the material for the first electrode 11, the third electrode 21, the fifth electrode 31, and the plurality of first conductor portions 51 and may be copper, for example. However, this is only an example and should not be construed as limiting. Alternatively, the material may also be, for example, a copper alloy, aluminum, or titanium. The second step includes forming, by electroplating process, for example, a first metal portion to be the first electrode 11, the third electrode 21, the fifth electrode 31, and the plurality of first conductor portions 51. The material for the first metal portion may be copper. However, this is only an example and should not be construed as limiting. Alternatively, the material for the first metal portion may also be, for example, a copper alloy, aluminum, or titanium. The third step includes forming the first electrode 11, the third electrode 21, the fifth electrode 31, and the plurality of first conductor portions 51 by subjecting the first metal portion to a chemical mechanical polishing (CMP) process until the thickness of the first metal portion decreases to the thickness of the first electrode 11, the third electrode 21, the fifth electrode 31, and the plurality of first conductor portions 51. In this embodiment, the first step includes forming the seed layer by sputtering. However, this is only an example and should not be construed as limiting. Alternatively, the first step may include forming the seed layer by electroless plating or chemical vapor deposition (CVD) process. Note that the third step includes subjecting the first resin layer 44 to the CMP process as well to expose the respective upper surfaces of the first electrode 11, the third electrode 21, the fifth electrode 31, and the plurality of first conductor portions 51 and to make the principal surface 440 of the first resin layer 44 substantially flush with the respective upper surfaces of the first electrode 11, the third electrode 21, the fifth electrode 31, and the plurality of first conductor portions 51.

The fourth process step includes forming a second resin layer 45 as a prototype of the second dielectric layer 42 to cover the respective upper surfaces of the first electrode 11, the third electrode 21, the fifth electrode 31, and the plurality of first conductor portions 51 and the principal surface 440 of the first resin layer 44 as shown in FIG. 2D. Examples of materials for the second resin layer 45 include an organic material (resin material) for the second dielectric layer 42. The fourth process step includes forming the second resin layer 45 by applying a solution including the organic material for the second resin layer 45 using a coater (such as a spin coater) or a dispenser to cover the respective upper surfaces of the first electrode 11, the third electrode 21, the fifth electrode 31, and the plurality of first conductor portions 51 and the principal surface 440 of the first resin layer 44 and prebaking the organic material thus applied.

The fifth process step includes forming, in the second resin layer 45, a first recess 451, a second recess 452, a third recess 453, and a plurality of fourth recesses 454 which respectively define regions where the second electrode 12, the fourth electrode 22, the sixth electrode 32, and the plurality of conductor portions (including the second conductor portion 52 and the via conductor portion 53) will be formed as shown in FIG. 3A. In this embodiment, the fifth process step includes forming the first recess 451, the second recess 452, the third recess 453, and the plurality of fourth recesses 454 in the second resin layer 45 by imprinting process (such as thermal imprinting process). More specifically, the fifth process step includes, first, providing a second mold (second die) where a second uneven pattern, of which the pattern is designed according to the respective shapes of the second electrode 12, the fourth electrode 22, the sixth electrode 32, and the plurality of conductor portions 5, has been formed. The fifth process step further includes deforming the second resin layer 45 after that by pressing the second mold against the second resin layer 45 and then causing the second resin layer 45 to cure (e.g., thermally), thereby forming the first recess 451, the second recess 452, the third recess 453, and the plurality of fourth recesses 454 where the second electrode 12, the fourth electrode 22, the sixth electrode 32, and the plurality of conductor portions will be respectively formed. Then, the second mold is removed from the second resin layer 45. The opening shape of the first recess 451 corresponds to the outer edge shape of the second electrode 12 in plan view and the depth of the first recess 451 corresponds to the thickness of the second electrode 12. The opening shape of the second recess 452 corresponds to the outer edge shape of the fourth electrode 22 in plan view and the depth of the second recess 452 corresponds to the thickness of the fourth electrode 22. The opening shape of the third recess 453 corresponds to the outer edge shape of the sixth electrode 32 in plan view and the depth of the third recess 453 corresponds to the thickness of the sixth electrode 32. The second recess 452 is deeper than the first recess 451. The third recess 453 is deeper than the second recess 452. Note that the imprinting process does not have to be a thermal imprinting process but may also be an optical imprinting process, for example.

The sixth process step includes forming the second electrode 12, the fourth electrode 22, the sixth electrode 32, the plurality of via conductor portions 53, and plurality of second conductor portions 52 as shown in FIG. 3B. More specifically, the sixth process step includes a first step, a second step, and a third step. The first step includes forming, by sputtering process, for example, a seed layer to cover the surface of the second resin layer 45. A material for the seed layer is the same as the material for the second electrode 12, the fourth electrode 22, the sixth electrode 32, the plurality of via conductor portions 53, and the plurality of second conductor portions 52 and may be copper, for example. However, this is only an example and should not be construed as limiting. Alternatively, the material may also be, for example, a copper alloy, aluminum, or titanium. The second step includes forming, by electroplating process, for example, a second metal portion to be the second electrode 12, the fourth electrode 22, the sixth electrode 32, the plurality of via conductor portions 53, and the plurality of second conductor portions 52. The material for the second metal portion may be copper, for example. However, this is only an example and should not be construed as limiting. Alternatively, the material for the second metal portion may also be, for example, a copper alloy, aluminum, or titanium. The third step includes forming the second electrode 12, the fourth electrode 22, the sixth electrode 32, the plurality of via conductor portions 53, and the plurality of second conductor portions 52 by subjecting the second metal portion to a CMP process until the thickness of the second metal portion decreases to the thickness of the second electrode 12, the fourth electrode 22, the sixth electrode 32, and the plurality of second conductor portions 52. In this embodiment, the first step includes forming the seed layer by sputtering. However, this is only an example and should not be construed as limiting. Alternatively, the first step may include forming the seed layer by electroless plating or a CVD process. Note that the third step includes subjecting the second resin layer 45 to the CMP process as well to expose the respective upper surfaces of the second electrode 12, the fourth electrode 22, the sixth electrode 32, and the plurality of second conductor portions 52 and to make the principal surface 450 of the second resin layer 45 substantially flush with the respective upper surfaces of the second electrode 12, the fourth electrode 22, the sixth electrode 32, and the plurality of second conductor portions 52. As a result, the second resin layer 45 that has been subjected to the CMP process serves as the second dielectric layer 42.

The seventh process step includes forming the first dielectric layer 41 out of the rest of the first resin layer 44 by subjecting the supporting substrate 9 and a part of the first resin layer 44 to a CMP process from the principal surface 92, facing away from the first resin layer 44, of the supporting substrate 9 (refer to FIG. 3C). The seventh process step includes subjecting the first resin layer 44 to the CMP process to expose the respective lower surfaces of the first electrode 11, the third electrode 21, the fifth electrode 31, and the plurality of first conductor portions 51 and to make the lower surface of the first resin layer 44 substantially flush with the respective lower surfaces of the first electrode 11, the third electrode 21, the fifth electrode 31, and the plurality of first conductor portions 51. Note that the seventh process step needs to include exposing the respective lower surfaces of the first electrode 11, the third electrode 21, the fifth electrode 31, and the plurality of first conductor portions 51 but may or may not include making the lower surface of the first resin layer 44 substantially flush with the respective lower surfaces of the first electrode 11, the third electrode 21, the fifth electrode 31, and the plurality of first conductor portions 51. Optionally, the seventh process step may include peeling off the supporting substrate 9 and then subjecting a part of the first resin layer 44 to the CMP process. For example, the first resin layer 44 may be formed in advance after an adhesive layer made of a glue such as acrylic or silicone or an adhesive has been formed on the supporting substrate 9 in the first process step. Thereafter, in the seventh process step, the supporting substrate 9 may be peeled off by decreasing the adhesion or adhesive force of the adhesive layer by heating or irradiating the supporting substrate 9 with an ultraviolet ray or a laser beam.

In the method for fabricating an interposer 100 according to the first embodiment, the interposer 100 is formed by performing the first through seventh process steps described above.

This method for fabricating an interposer 100 according to the first embodiment uses an imprinting process, and therefore, eliminates the need to perform the photolithographic and etching processes that are used in a semiconductor fabrication process, thus contributing cutting down the cost of the interposer 100.

### (4) Advantages

An interposer 100 according to the first embodiment includes a dielectric substrate 4, and a first capacitor 1, a second capacitor 2, and a third capacitor 3 which are built in the dielectric substrate 4. In this interposer 100, the first capacitor 1, the second capacitor 2, and the third capacitor 3 have mutually different capacitances. In this interposer 100, the thickness T2 of a second dielectric portion 23 is less than the thickness T1 of a first dielectric portion 13, and the capacitance of the second capacitor 2 is greater than the capacitance of the first capacitor 1. In addition, in this interposer 100, the thickness T3 of a third dielectric portion 33 is less than the thickness T2 of the second dielectric portion 23 and the capacitance of the third capacitor 3 is greater than the capacitance of the second capacitor 2. Thus, the interposer 100 according to the first embodiment includes a plurality of capacitors (namely, the first capacitor 1, the second capacitor 2, and the third capacitor 3) having mutually different capacitances and yet may contribute to downsizing. More specifically, in the interposer 100 according to the first embodiment, the first capacitor 1, the second capacitor 2, and the third capacitor 3 have mutually different unit capacitances (each of which represents the capacitance per unit area), and therefore, may contribute to downsizing more effectively than making the respective capacitances of the first capacitor 1, the second capacitor 2, and the third capacitor 3 different from each other by changing their respective areas when viewed in plan in the thickness direction D1 defined with respect to the dielectric substrate 4. In addition, in the interposer 100 according to the first embodiment, the thickness T2 of the second dielectric portion 23 of the second capacitor 2 is greater than the thickness T3 of the third dielectric portion 33 of the third capacitor 3, thus allowing for making the reliability of the second capacitor 2 higher than the reliability of the third capacitor 3. In other words, in the interposer 100 according to the first embodiment, the thickness T2 of the second dielectric portion 23 of the second capacitor 2 is greater than the thickness T3 of the third dielectric portion 33 of the third capacitor 3, thus allowing for making the time it takes for the second capacitor 2 to cause a time dependent dielectric breakdown (TDDB) longer than the time it takes for the third capacitor 3 to cause the TDDB. Furthermore, in the interposer 100 according to the first embodiment, the thickness T1 of the first dielectric portion 13 of the first capacitor 1 is greater than the thickness T2 of the second dielectric portion 23 of the second capacitor 2, thus allowing for making the reliability of the first capacitor 1 higher than the reliability of the second capacitor 2. In other words, in the interposer 100 according to the first embodiment, the thickness T1 of the first dielectric portion 13 of the first capacitor 1 is greater than the thickness T2 of the second dielectric portion 23 of the second capacitor 2, thus allowing for making the time it takes for the first capacitor 1 to cause a TDDB longer than the time it takes for the second capacitor 2 to cause the TDDB.

### Second Embodiment

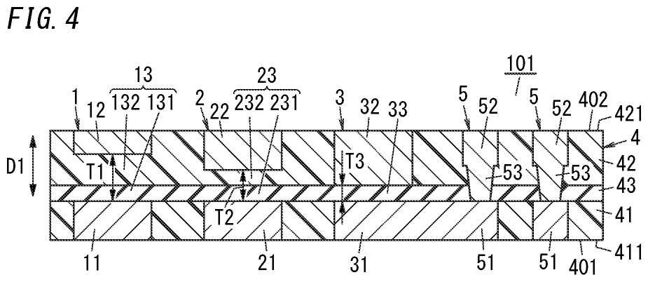

Next, an interposer 101 according to a second embodiment will be described with reference to FIG. 4. In the following description, any constituent element of the interposer 101 according to this second embodiment, having the same function as a counterpart of the interposer 100 according to the first embodiment (refer to FIG. 1) described above, will be designated by the same reference numeral as that counterpart's, and description thereof will be omitted herein.

### (1) Configuration

In an interposer 101 according to the second embodiment, the dielectric substrate 4 further includes a third dielectric layer 43, which is a difference from the interposer 100 according to the first embodiment.

The third dielectric layer 43 is interposed between the first dielectric layer 41 and the second dielectric layer 42 in the thickness direction D1 defined with respect to the dielectric substrate 4. That is to say, in the interposer 101 according to the second embodiment, the second dielectric layer 42 is stacked over the first dielectric layer 41 via the third dielectric layer 43. In the interposer 101 according to the second embodiment, a material for the first dielectric portion 13, a material for the second dielectric portion 23, and a material for the second dielectric layer 42 include an organic material. A material for the third dielectric layer 43 is an inorganic material. Examples of the inorganic material include silicon nitride and silicon oxynitride.

In the interposer 101 according to the second embodiment, the first dielectric portion 13 includes a first part 131 formed integrally with the third dielectric layer 43 and a second part 132 formed integrally with the second dielectric layer 42. In the first dielectric portion 13, the first part 131 and the second part 132 are laid one on top of the other in the thickness direction D1 defined with respect to the dielectric substrate 4. The dielectric constant of the first part 131 of the first dielectric portion 13 is greater than the dielectric constant of the second part 132 thereof.

The second dielectric portion 23 includes a third part 231 formed integrally with the third dielectric layer 43 and a fourth part 232 formed integrally with the second dielectric layer 42. In the second dielectric portion 23, the third part 231 and the fourth part 232 are laid one on top of the other in the thickness direction D1 defined with respect to the dielectric substrate 4. The dielectric constant of the third part 231 of the second dielectric portion 23 is greater than the dielectric constant of the fourth part 232 thereof.

The third dielectric portion 33 is formed integrally with the third dielectric layer 43. The thickness T3 of the third dielectric portion 33 is equal to the thickness of the third dielectric layer 43. The dielectric constant of the third dielectric portion 33 is greater than the dielectric constant of the fourth part 232 of the second dielectric portion 23.

In the interposer 101 according to the second embodiment, as well as in the interposer 100 according to the first embodiment, the thickness T2 of the second dielectric portion 23 is less than the thickness T1 of the first dielectric portion 13 and the capacitance of the second capacitor 2 is greater than the capacitance of the first capacitor 1. In addition, in the interposer 101 according to the second embodiment, as well as in the interposer 100 according to the first embodiment, the thickness T3 of the third dielectric portion 33 is less than the thickness T2 of the second dielectric portion 23 and the capacitance of the third capacitor 3 is greater than the capacitance of the second capacitor 2.

### (2) Fabricating Method

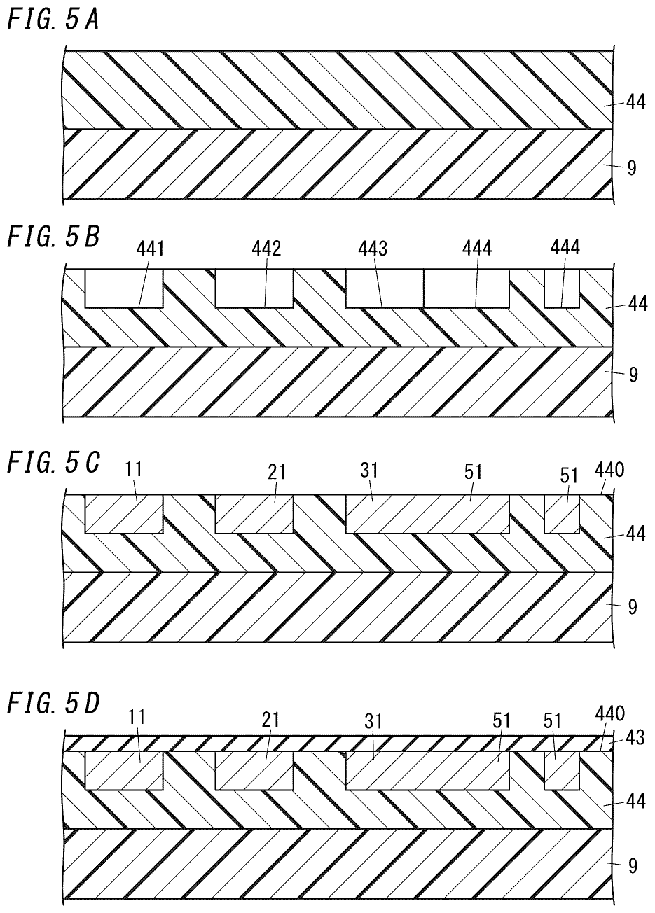

A method for fabricating the interposer 101 according to the second embodiment will be described with reference to FIGS. 5A-7B. The method for fabricating the interposer 101 according to the second embodiment is almost the same as the method for fabricating the interposer 100 according to the first embodiment but is different from the method for fabricating the interposer 100 according to the first embodiment in that the third dielectric layer 43 is formed. Thus, as for the method for fabricating the interposer 101 according to the second embodiment, description of the same process steps as the counterparts of the method for fabricating the interposer 100 according to the first embodiment will be omitted herein as appropriate.

According to a method for fabricating the interposer 101, a supporting substrate 9 is provided and then first through ninth process steps are performed sequentially. The supporting substrate 9 may be, for example, an organic film, a silicon substrate, a glass substrate, or a metal substrate.

The first process step includes forming a first resin layer 44 as a prototype of the first dielectric layer 41 on the supporting substrate 9 as shown in FIG. 5A. The first resin layer 44 is thicker than the first dielectric layer 41. The first process step includes forming the first resin layer 44 by applying a solution including an organic material for the first dielectric layer 41 onto the supporting substrate 9 using a coater (such as a spin coater) or a dispenser and prebaking the organic material thus applied.

The second process step includes forming, in the first resin layer 44, a first recess 441, a second recess 442, a third recess 443, and a plurality of fourth recesses 444 which respectively define regions where the first electrode 11, the third electrode 21, the fifth electrode 31, and the plurality of first conductor portions 51 will be formed as shown in FIG. 5B. In this embodiment, the second process step includes forming the first recess 441, the second recess 442, the third recess 443, and the plurality of fourth recesses 444 in the first resin layer 44 by imprinting process (such as thermal imprinting process).

The third process step includes forming the first electrode 11, the third electrode 21, the fifth electrode 31, and the plurality of first conductor portions 51 as shown in FIG. 5C. More specifically, the third process step includes a first step, a second step, and a third step. The first step includes forming, by sputtering process, for example, a seed layer to cover the surface of the first resin layer 44. The second step includes forming, by electroplating process, for example, a first metal portion to be the first electrode 11, the third electrode 21, the fifth electrode 31, and the plurality of first conductor portions 51. The third step includes forming the first electrode 11, the third electrode 21, the fifth electrode 31, and the plurality of first conductor portions 51 by subjecting the first metal portion to a CMP process until the thickness of the first metal portion decreases to the thickness of the first electrode 11, the third electrode 21, the fifth electrode 31, and the plurality of first conductor portions 51.

The fourth process step includes forming a third dielectric layer 43 by CVD process, for example, to cover the respective upper surfaces of the first electrode 11, the third electrode 21, the fifth electrode 31, and the plurality of first conductor portions 51 and the principal surface 440 of the first resin layer 44 with the third dielectric layer 43 as shown in FIG. 5D.

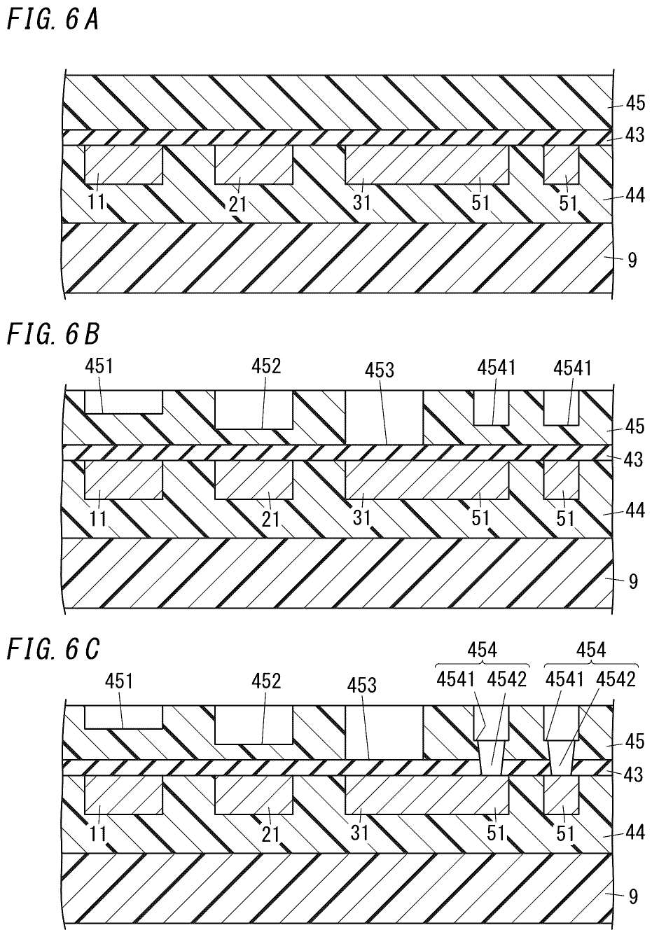

The fifth process step includes forming a second resin layer 45 as a prototype of the second dielectric layer 42 to cover the third dielectric layer 43 as shown in FIG. 6A. The fifth process step includes forming the second resin layer 45 by applying a solution including an organic material for the second resin layer 45 using a coater (such as a spin coater) or a dispenser to cover the third dielectric layer 43 and prebaking the organic material thus applied.

The sixth process step includes forming, in the second resin layer 45, a first recess 451, a second recess 452, a third recess 453, and a plurality of fifth recesses 4541 which respectively define regions where the second electrode 12, the fourth electrode 22, the sixth electrode 32, and the plurality of second conductor portions 52 will be formed as shown in FIG. 6B. In this embodiment, the sixth process step includes forming the first recess 451, the second recess 452, the third recess 453, and the plurality of fifth recesses 4541 in the second resin layer 45 by imprinting process (such as thermal imprinting process). In the sixth process step, the third dielectric layer 43 serves as a stopper that limits the depth of the third recess 453 to be formed by using the second mold.

The seventh process step includes cutting via holes 4542, respectively corresponding to a plurality of via conductor portions 53, through the second resin layer 45 and the third dielectric layer 43 by laser machining, for example, as shown in FIG. 6C. Each fourth recess 454 defining a region where conductor portions, including the second conductor portion 52 and the via conductor portion 53, will be formed includes the fifth recess 4541 and the via hole 4542.

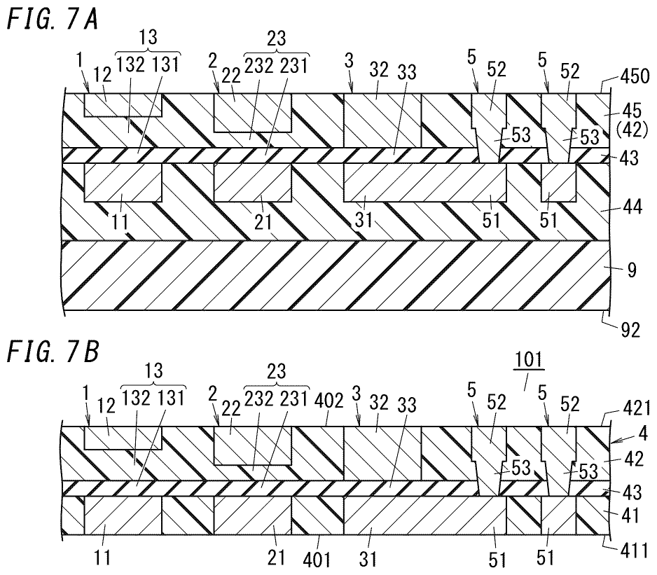

The eighth process step includes forming the second electrode 12, the fourth electrode 22, the sixth electrode 32, the plurality of via conductor portions 53, and the plurality of second conductor portions 52 as shown in FIG. 7A. More specifically, the eighth process step includes a first step, a second step, and a third step. The first step includes forming, by sputtering process, for example, a seed layer to cover the surface of the second resin layer 45. A material for the seed layer is the same as the material for the second electrode 12, the fourth electrode 22, the sixth electrode 32, the plurality of via conductor portions 53, and the plurality of second conductor portions 52 and may be copper, for example. However, this is only an example and should not be construed as limiting. Alternatively, the material may also be, for example, a copper alloy, aluminum, or titanium. The second step includes forming, by electroplating process, for example, a second metal portion to be the second electrode 12, the fourth electrode 22, the sixth electrode 32, the plurality of via conductor portions 53, and the plurality of second conductor portions 52. The material for the second metal portion may be copper, for example. However, this is only an example and should not be construed as limiting. Alternatively, the material for the second metal portion may also be, for example, a copper alloy, aluminum, or titanium. The third step includes forming the second electrode 12, the fourth electrode 22, the sixth electrode 32, the plurality of via conductor portions 53, and the plurality of second conductor portions 52 by subjecting the second metal portion to a CMP process until the thickness of the second metal portion decreases to the thickness of the second electrode 12, the fourth electrode 22, the sixth electrode 32, and the plurality of second conductor portions 52. Note that the third step includes subjecting the second resin layer 45 to the CMP process as well to expose the respective upper surfaces of the second electrode 12, the fourth electrode 22, the sixth electrode 32, and the plurality of second conductor portions 52 and to make the principal surface 450 of the second resin layer 45 substantially flush with the respective upper surfaces of the second electrode 12, the fourth electrode 22, the sixth electrode 32, and the plurality of second conductor portions 52. As a result, the second resin layer 45 that has been subjected to the CMP process serves as the second dielectric layer 42.

The ninth process step includes forming the first dielectric layer 41 out of the rest of the first resin layer 44 by subjecting the supporting substrate 9 and a part of the first resin layer 44 to a CMP process from the principal surface 92, facing away from the first resin layer 44, of the supporting substrate 9 (refer to FIG. 7B). The ninth process step includes subjecting the first resin layer 44 to the CMP process to expose the respective lower surfaces of the first electrode 11, the third electrode 21, the fifth electrode 31, and the plurality of first conductor portions 51 and to make the lower surface of the first resin layer 44 substantially flush with the respective lower surfaces of the first electrode 11, the third electrode 21, the fifth electrode 31, and the plurality of first conductor portions 51. Note that the ninth process step needs to include exposing the respective lower surfaces of the first electrode 11, the third electrode 21, the fifth electrode 31, and the plurality of first conductor portions 51 but may or may not include making the lower surface of the first resin layer 44 substantially flush with the respective lower surfaces of the first electrode 11, the third electrode 21, the fifth electrode 31, and the plurality of first conductor portions 51.

In the method for fabricating an interposer 101 according to the second embodiment, the interposer 101 is formed by performing the first through ninth process steps described above.

### (3) Advantages

In an interposer 101 according to the second embodiment, as well as the interposer 100 according to the first embodiment, the first capacitor 1, the second capacitor 2, and the third capacitor 3 have mutually different capacitances. In the interposer 101 according to the second embodiment, as well as in the interposer 100 according to the first embodiment, the thickness T2 of the second dielectric portion 23 is less than the thickness T1 of the first dielectric portion 13, and the capacitance of the second capacitor 2 is greater than the capacitance of the first capacitor 1. In addition, in this interposer 100, the thickness T3 of the third dielectric portion 33 is less than the thickness T2 of the second dielectric portion 23 and the capacitance of the third capacitor 3 is greater than the capacitance of the second capacitor 2. Thus, the interposer 101 according to the second embodiment, as well as the interposer 100 according to the first embodiment, includes a plurality of capacitors (namely, the first capacitor 1, the second capacitor 2, and the third capacitor 3) having mutually different capacitances and yet may contribute to downsizing.

In addition, in the interposer 101 according to the second embodiment, the dielectric substrate 4 includes the third dielectric layer 43, having a greater dielectric constant than any of the first dielectric layer 41 or the second dielectric layer 42, thus allowing for making the respective capacitances of the first capacitor 1, the second capacitor 2, and the third capacitor 3 greater than the respective capacitances of the first capacitor 1, the second capacitor 2, and the third capacitor 3 of the interposer 100 according to the first embodiment described above. Furthermore, the interposer 101 according to the second embodiment may reduce the non-uniformity in the thickness of the third dielectric portion 33, and therefore, may reduce the non-uniformity in the capacitance of the third capacitor 3.

Besides, in the interposer 101 according to the second embodiment, the material for the third dielectric layer 43 includes either silicon nitride or silicon oxynitride (stated otherwise, the third dielectric layer 43 is configured as either a silicon nitride layer or a silicon oxynitride layer). This may reduce the diffuse of copper, which is one of constituent elements of each of the first electrode 11, the third electrode 21, and the fifth electrode 31, thus allowing for improving the electromigration resistance and/or extending the time it takes to cause a TDDB. Note that the material for the third dielectric layer 43 does not have to be silicon nitride or silicon oxynitride as long as the material is an inorganic material.

### Variations

Note that the first and second embodiments and their variations described above are only exemplary ones of various embodiments of the present disclosure and their variations and should not be construed as limiting. Rather, the first and second exemplary embodiments and their variations may be readily modified in various manners depending on a design choice or any other factor without departing from the scope of the present disclosure.

For example, in the embodiments described above, the interposer 100, 101 includes the third capacitor 3. However, the interposer 100, 101 may also have a configuration without the third capacitor 3. Also, the interposer 100, 101 only needs to include a plurality of capacitors including at least the first capacitor 1 and the second capacitor 2 and does not have to include the third capacitor 3. Alternatively, the interposer 100, 101 may include four or more capacitors including the first capacitor 1 and the second capacitor 2 if their respective dielectric portions have mutually different thicknesses and if their capacitances are different from each other. Optionally, the plurality of capacitors may include two capacitors, of which the capacitances are equal to each other.

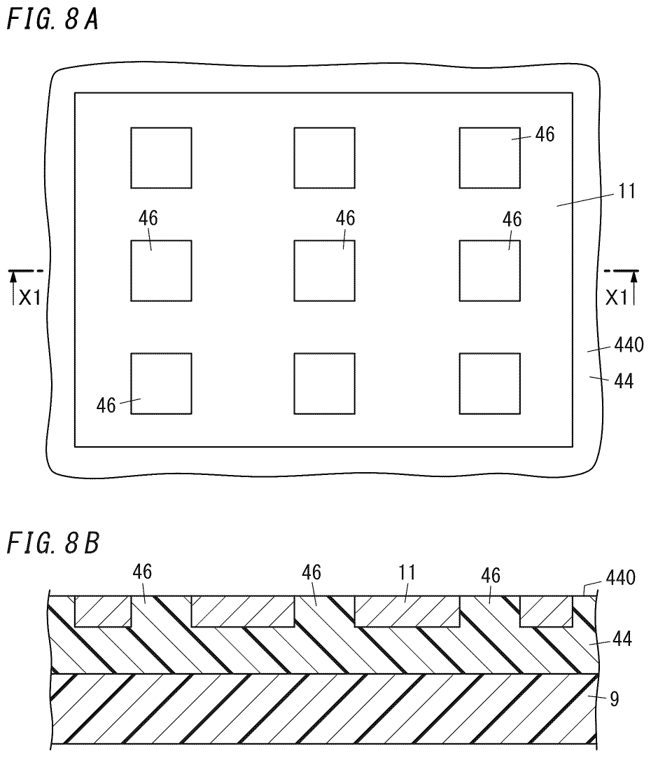

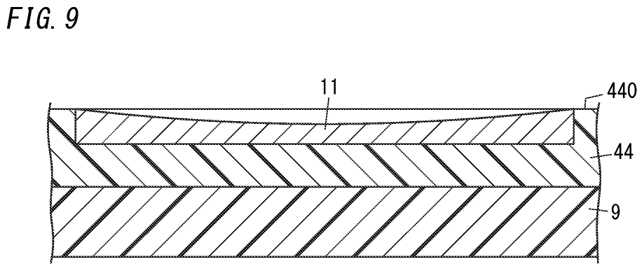

Optionally, the method for fabricating the interposer 100, 101 may include forming a plurality of insulating pillars 46 penetrating through the first electrode 11 as shown in FIGS. 8A and 8B. According to a method for fabricating the interposer 100, 101, if the area of the first electrode 11 is increased, for example, then the CMP process in the third process step may produce dishing, thus sometimes causing a decrease in planarity as shown in FIG. 9. On the other hand, providing the plurality of insulating pillars 46 that penetrate through the first electrode 11 before performing the third process step may reduce the chances of producing dishing as a result of the CMP process and thereby reduce the non-uniformity in the capacitance of the first capacitor 1. Note that only the first electrode 11 is shown in FIGS. 8A and 8B out of the first electrode 11, the third electrode 21, and the fifth electrode 31. Optionally, the plurality of insulating pillars 46 may also be provided for each of the third electrode 21 and the fifth electrode 31.

The material for the plurality of insulating pillars 46 may be the same as, for example, the material for the first resin layer 44. The plurality of insulating pillars 46 are formed integrally with the first resin layer 44. Therefore, in the interposer 100, 101, the material for the plurality of insulating pillars 46 is the same as the material for the first dielectric layer 41.

Optionally, the interposer 100, 101 may include the supporting substrate 9. In that case, the first resin layer 44 (refer to FIGS. 3B and 7A) may serve as the first dielectric layer 41 and the supporting substrate 9 may be provided with, for example, a plurality of feedthrough wiring portions connected one to one to the first capacitor 1, the second capacitor 2, the third capacitor 3, and the respective wiring portions 5.

Furthermore, in the interposer 100, the material for each of the first dielectric layer 41 and the second dielectric layer 42 does not have to be an organic material but may also be an inorganic material (such as a ceramic).

Optionally, in the interposer 100, the dielectric substrate 4 may include not only the first dielectric layer 41 and the second dielectric layer 42 but also at least one more dielectric layer. In the interposer 100, the dielectric substrate 4 may include not only the first dielectric layer 41, the second dielectric layer 42, and the third dielectric layer 43 but also at least one more dielectric layer.

Furthermore, in the interposer 100, 101, the dielectric substrate 4 includes a plurality of dielectric layers. However, the interposer 100, 101 does not have to include a plurality of dielectric layers.

Optionally, in the interposer 101, the material for the third dielectric layer 43 may be an organic material having a higher Young's modulus than any of the material for the first dielectric portion 13, the material for the second dielectric portion 23, or the material for the second dielectric layer 42.

### Aspects

The foregoing description provides specific implementations for the following aspects of the present disclosure.

An interposer (100; 101) according to a first aspect includes a dielectric substrate (4), a wiring portion (5), and a first capacitor (1) and a second capacitor (2). The dielectric substrate (4) has a first principal surface (401) and a second principal surface (402) opposite from the first principal surface (401). The wiring portion (5) penetrates through the dielectric substrate (4). The first capacitor (1) and the second capacitor (2) are built in the dielectric substrate (4). The first capacitor (1) and the second capacitor (2) have mutually different capacitances. The first capacitor (1) includes a first electrode (11) and a second electrode (12), and a first dielectric portion (13). The first electrode (11) and the second electrode (12) face each other in a thickness direction (D1) defined with respect to the dielectric substrate (4). The first dielectric portion (13) is interposed between the first electrode (11) and the second electrode (12). The second capacitor (2) includes a third electrode (21) and a fourth electrode (22), and a second dielectric portion (23). The third electrode (21) and the fourth electrode (22) face each other in the thickness direction (D1) defined with respect to the dielectric substrate (4). The second dielectric portion (23) is interposed between the third electrode (21) and the fourth electrode (22). The thickness (T2) of the second dielectric portion (23) is less than the thickness (T1) of the first dielectric portion (13). The capacitance of the second capacitor (2) is greater than the capacitance of the first capacitor (1).

This aspect may contribute to downsizing while providing a plurality of capacitors (namely, the first capacitor 1 and the second capacitor 2) with mutually different capacitances.

In an interposer (100; 101) according to a second aspect, which may be implemented in conjunction with the first aspect, the dielectric substrate (4) includes a first dielectric layer (41) and a second dielectric layer (42). The second dielectric layer (42) is stacked on the first dielectric layer (41). The first electrode (11) and the third electrode (21) are built in the first dielectric layer (41). The second electrode (12) and the fourth electrode (22) are built in the second dielectric layer (42).

In an interposer (100; 101) according to a third aspect, which may be implemented in conjunction with the second aspect, the first dielectric portion (13) and the second dielectric portion (23) overlap with the second dielectric layer (42) in a direction perpendicular to the thickness direction (D1) defined with respect to the dielectric substrate (4). A material for the first dielectric portion (13), a material for the second dielectric portion (23), and a material for the second dielectric layer (42) include an organic material.

In an interposer (100; 101) according to a fourth aspect, which may be implemented in conjunction with the second or third aspect, a material for the first dielectric layer (41) is the same as a material for the second dielectric layer (42).

This aspect allows for increasing the degree of adhesion between the first dielectric layer (41) and the second dielectric layer (42).

In an interposer (101) according to a fifth aspect, which may be implemented in conjunction with the second aspect, the dielectric substrate (4) further includes a third dielectric layer (43). The third dielectric layer (43) is interposed between the first dielectric layer (41) and the second dielectric layer (42). A material for the first dielectric portion (13), a material for the second dielectric portion (23), and a material for the second dielectric layer (42) include an organic material. A material for the third dielectric layer (43) is an organic material having a higher Young's modulus than any of the material for the first dielectric portion (13), the material for the second dielectric portion (23), or the material for the second dielectric layer (42). The first dielectric portion (13) includes: a first part (131) formed integrally with the third dielectric layer (43); and a second part (132) formed integrally with the second dielectric layer (42). The second dielectric portion (23) includes a third part (231) formed integrally with the third dielectric layer (43).

In an interposer (101) according to a sixth aspect, which may be implemented in conjunction with the second aspect, the dielectric substrate (4) further includes a third dielectric layer (43). The third dielectric layer (43) is interposed between the first dielectric layer (41) and the second dielectric layer (42). A material for the third dielectric layer (43) is an inorganic material.

In an interposer (100; 101) according to a seventh aspect, which may be implemented in conjunction with any one of the second to sixth aspects, the wiring portion (5) includes a first conductor portion (51), a second conductor portion (52), and a via conductor portion (53). The first conductor portion (51) penetrates through the first dielectric layer (41). The second conductor portion (52) is built in the second dielectric layer (42). The second conductor portion (52) is less thick than the second dielectric layer (42) and is exposed out of the second principal surface (402) of the dielectric substrate (4). The via conductor portion (53) is built in the second dielectric layer (42) and connects the first conductor portion (51) and the second conductor portion (52) to each other.

In an interposer (100; 101) according to an eighth aspect, which may be implemented in conjunction with any one of the first to seventh aspects, the first electrode (11), the second electrode (12), the third electrode (21), the fourth electrode (22), and the wiring portion (5) all include the same metal.

This aspect contributes to cutting down the cost.

### REFERENCE SIGNS LIST

1 First Capacitor
11 First Electrode
12 Second Electrode
13 First Dielectric Portion
131 First Part
132 Second Part
2 Second Capacitor
21 Third Electrode
22 Fourth Electrode
23 Second Dielectric Portion
231 Third Part
232 Fourth Part
3 Third Capacitor
31 Fifth Electrode
32 Sixth Electrode
33 Third Dielectric Portion
4 Dielectric Substrate
41 First Dielectric Layer
42 Second Dielectric Layer
43 Third Dielectric Layer
401 First Principal Surface
5 Wiring Portion
51 First Conductor Portion
52 Second Conductor Portion
53 Via Conductor Portion
100, 101 Interposer
D1 Thickness Direction
T1 Thickness
T2 Thickness
T3 Thickness

1-8. (canceled)

9. An interposer comprising:
a dielectric substrate having a first principal surface and a second principal surface opposite from the first principal surface;
a wiring portion penetrating through the dielectric substrate; and
a first capacitor and a second capacitor which are built in the dielectric substrate and have mutually different capacitances,
the first capacitor including:
a first electrode and a second electrode facing each other in a thickness direction defined with respect to the dielectric substrate; and
a first dielectric portion interposed between the first electrode and the second electrode,
the second capacitor including:
a third electrode and a fourth electrode facing each other in the thickness direction defined with respect to the dielectric substrate; and
a second dielectric portion interposed between the third electrode and the fourth electrode,
thickness of the second dielectric portion being less than thickness of the first dielectric portion, and
capacitance of the second capacitor being greater than capacitance of the first capacitor.

10. The interposer of claim 9, wherein
the dielectric substrate includes:
a first dielectric layer; and
a second dielectric layer stacked on the first dielectric layer,
the first electrode and the third electrode are built in the first dielectric layer, and
the second electrode and the fourth electrode are built in the second dielectric layer.

11. The interposer of claim 10, wherein
the first dielectric portion and the second dielectric portion overlap with the second dielectric layer in a direction perpendicular to the thickness direction defined with respect to the dielectric substrate, and
a material for the first dielectric portion, a material for the second dielectric portion, and a material for the second dielectric layer include an organic material.

12. The interposer of claim 10, wherein
a material for the first dielectric layer is same as a material for the second dielectric layer.

13. The interposer of claim 10, wherein
the dielectric substrate further includes a third dielectric layer interposed between the first dielectric layer and the second dielectric layer,
a material for the first dielectric portion, a material for the second dielectric portion, and a material for the second dielectric layer include an organic material,
a material for the third dielectric layer is an organic material having a higher Young's modulus than any of the material for the first dielectric portion, the material for the second dielectric portion, or the material for the second dielectric layer,
the first dielectric portion includes:
a first part formed integrally with the third dielectric layer; and
a second part formed integrally with the second dielectric layer, and
the second dielectric portion includes
a third part formed integrally with the third dielectric layer.

14. The interposer of claim 10, wherein
the dielectric substrate includes a third dielectric layer interposed between the first dielectric layer and the second dielectric layer, and
a material for the third dielectric layer is an inorganic material.

15. The interposer of claim 10, wherein
the wiring portion includes:
a first conductor portion penetrating through the first dielectric layer;
a second conductor portion built in the second dielectric layer, the second conductor portion being less thick than the second dielectric layer and exposed out of the second principal surface of the dielectric substrate; and
a via conductor portion built in the second dielectric layer and connecting the first conductor portion and the second conductor portion to each other.

16. The interposer of claim 9, wherein
the first electrode, the second electrode, the third electrode, the fourth electrode, and the wiring portion all include same metal.
